(19) United States
(12) Patent Application Publication
(10) Pub. No.: US 2015/0097174 A1
(43) Pub. Date: Apr. 9, 2015

(54) RESIN COMPOSITION, SUBSTRATE, METHOD OF MANUFACTURING ELECTRONIC DEVICE AND ELECTRONIC DEVICE

(71) Applicants: AKRON POLYMER SYSTEMS INC., Akron, OH (US); SUMITOMO BAKELITE COMPANY LIMITED, Shinagawa-ku (JP)

(72) Inventors: Limin SUN, Copley, OH (US); Dong ZHANG, Uniontown, OH (US); Jiaokai JING, Uniontown, OH (US); Frank W. HARRIS, Boca Raton, FL (US); Hideo UMEDA, Kobe City (JP); Jun OKADA, Kobe City (JP); Manabu NAITO, Kobe City (JP)

(73) Assignees: AKRON POLYMER SYSTEMS INC., Akron, OH (US); SUMITOMO BAKELITE COMPANY LIMITED, Shinagawa-ku (JP)

(21) Appl. No.: 14/505,971

(22) Filed: Oct. 3, 2014

Related U.S. Application Data
(60) Provisional application No. 61/886,999, filed on Oct. 4, 2013.
(60) Provisional application No. 61/887,095, filed on Oct. 4, 2013.

(51) Int. Cl. C08L 77/06; H01L 51/52; H01L 51/44; H01L 51/56

(52) U.S. Cl. CPC C08L 77/06; H01L 51/56; H01L 51/5253; H01L 51/448
USPC 257/40; 524/607; 428/474.4; 428/335; 438/127

(57) ABSTRACT

Provided are a resin composition and a substrate that are capable of being used for manufacturing an electronic device having excellent light extraction efficiency. The resin composition contains a crystalline polymer and a solvent dissolving the crystalline polymer. The resin composition is used to form a layer, and a haze value of the layer is 5% or more. Further, a method of manufacturing the electronic device by using such a substrate, and the electronic device are also provided.

### CROSS-REFERENCE TO RELATED APPLICATIONS

The present application is based upon and claims the benefit of priority to U.S. Application No. 61/886,999, filed Oct. 4, 2013, and No. 61/887,095, filed Oct. 4, 2013. The entire contents of these applications are incorporated herein by reference.

### TECHNICAL FIELD

The present invention relates to a resin composition, a substrate, a method of manufacturing an electronic device and an electronic device.

### BACKGROUND ART

In an illuminating device (electronic device) such as an organic EL (electroluminescence) illuminating device and a light emitting diode illuminating device, it is required that a substrate used therein should have transparency. Therefore, as such a substrate used in the illuminating device, it is known to use a substrate formed of a transparent resin material such as polyethylene terephthalate and polycarbonate (for example, the patent document 1).

In such an illuminating device, when light is emitted from a light emitting element provided in the illuminating device, the emitted light passes through the transparent substrate and then is extracted outside the illuminating device. Namely, the light emitted from the light emitting element transmits out to the device through the transparent substrate and then reaches to a targeted object. In this way, the targeted object is illuminated with the light.

Regarding the passing of the light through the substrate, if a haze value of the substrate through which the light passes is high, light diffuseness of the substrate becomes higher. When the light diffuseness of the substrate becomes higher, light extraction efficiency of the light is also improved because the substrate having high light diffuseness can make a leak of the light through edges of the substrate hardly occur. Thus, by improving the light diffuseness of the substrate, it is possible to make the light extraction efficiency of the device high.

As such technique which can improve the light diffuseness of the substrate, it is known to add a granular resin into the substrate (for example, the patent document 2). In this case, there is a case where heat resistance of the substrate becomes lower due to the addition of an organic filler (granular resin). Further, in the case where a film (used as the substrate) is formed by applying a varnish containing a transparent resin material onto a glass plate and then drying it, there is a case where the substrate becomes easily broken when the substrate is peeled off from the glass plate.

The patent document 1: JP-A 2009-289460

The patent document 2: JP-A H08-146207

### SUMMARY OF THE INVENTION

It is an object of the present invention to provide a resin composition and a substrate that are capable of being used for manufacturing an electronic device having excellent light extraction efficiency. It is another object of the present invention to provide a method of manufacturing the electronic device using such a substrate and the electronic device.

In order to achieve the objects described above, the present invention includes the following features (1) to (26).

(1) A resin composition comprising:

a crystalline polymer; and

a solvent dissolving the crystalline polymer,

wherein the resin composition is used to form a layer, and a haze value of the layer is 5% or more.

(2) The resin composition according to the above (1), wherein the crystalline polymer is an aromatic polyamide.

(3) The resin composition according to the above (2), wherein the aromatic polyamide contains a carboxyl group.

(4) The resin composition according to the above (2), wherein the aromatic polyamide contains a rigid structure in an amount of 85 mol % or more.

(5) The resin composition according to the above (4), wherein the rigid structure is a repeating unit represented by the following general formula:

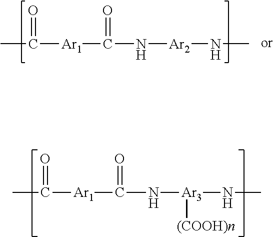

where n represents an integer number of 1 to 4, Ar₁ is represented by the following general formula (A) or (B):

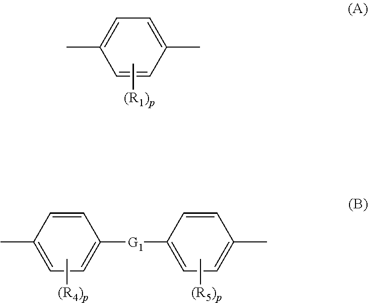

(where p=4; each of R₁, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).); and Ar₂ is represented by the following general formula (C) or (D):

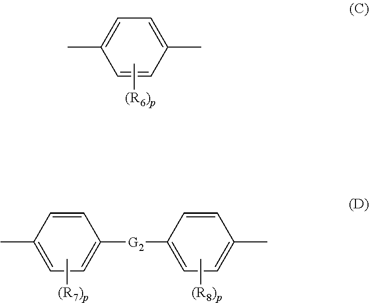

(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Ar₃ is represented by the following general formula (E) or (F):

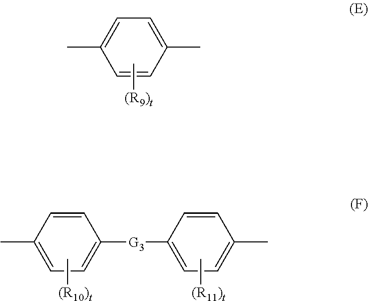

(where t=1 to 3; each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₃ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

(6) The resin composition according to the above (5), wherein the rigid structure contains at least one of a structure derived from 4,4′-diamino-2,2′-bistrifluoromethyl benzidine (PFMB), a structure derived from terephthaloyl dichloride (TPC), a structure derived from 4,4′-diaminodiphenic acid (DADP), and a structure derived from 3,5-diaminobenzoic acid (DAB).

(7) The resin composition according to the above (2), wherein the aromatic polyamide is a wholly aromatic polyamide.

(8) The resin composition according to the above (2), wherein the aromatic polyamide contains one or more functional groups that can react with an epoxy group, and
wherein the resin composition further comprises a multifunctional epoxide.

(9) The resin composition according to the above (8), wherein at least one terminal of the aromatic polyamide is the functional group that can react with the epoxy group.

(10) The resin composition according to the above (8), wherein the multifunctional epoxide is an epoxide containing two or more glycidyl epoxy groups, or an epoxide containing two or more alicyclic groups.

(11) The resin composition according to the above (8), wherein the multifunctional epoxide is selected from the group consisting of general structures (α) and (β):

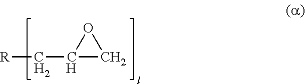

(where 1 represents the number of glycidyl group, and R is selected from the group comprising:

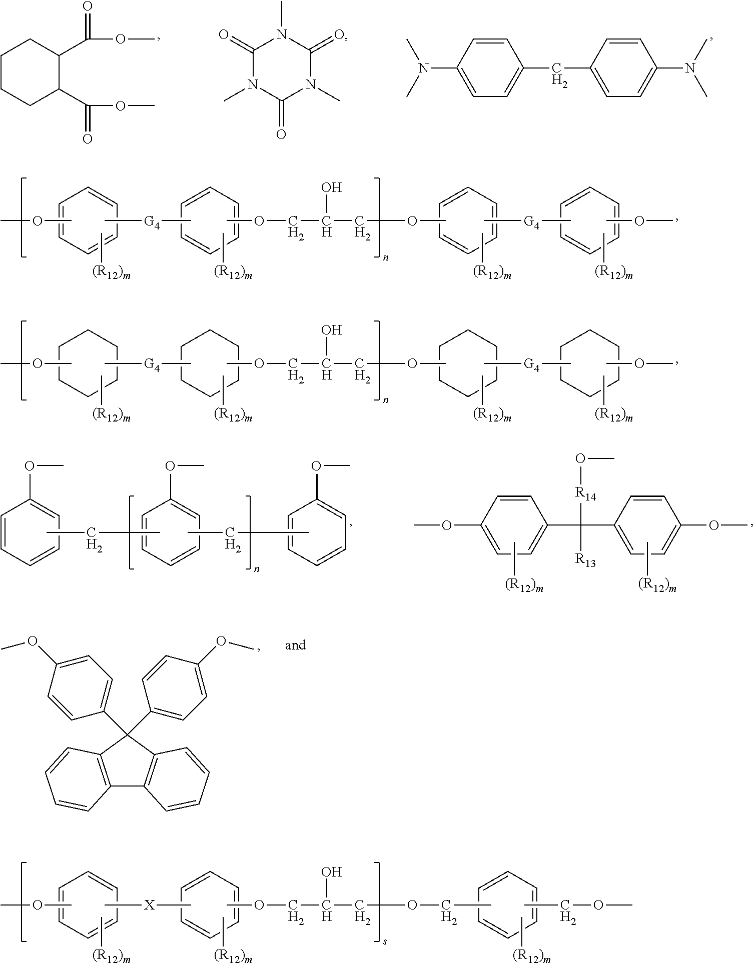

where m=1 to 4, and n and s are the average number of units and independently range from of 0 to 30;

where each of R₁₂ is same or different, and selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₄ is selected from the group consisting of a covalent bond, a CH₂ group, a C(CH₃)₂ group, a C(CF₃)₂ group, a C(CX₃)₂ group (X represents a halogen atom); a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group, R₁₃ is a hydrogen or methyl group, and R₁₄ is a divalent organic group.).)

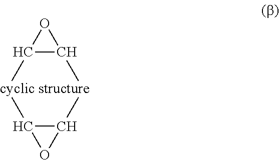

(where the cyclic structure is selected from the group comprising:

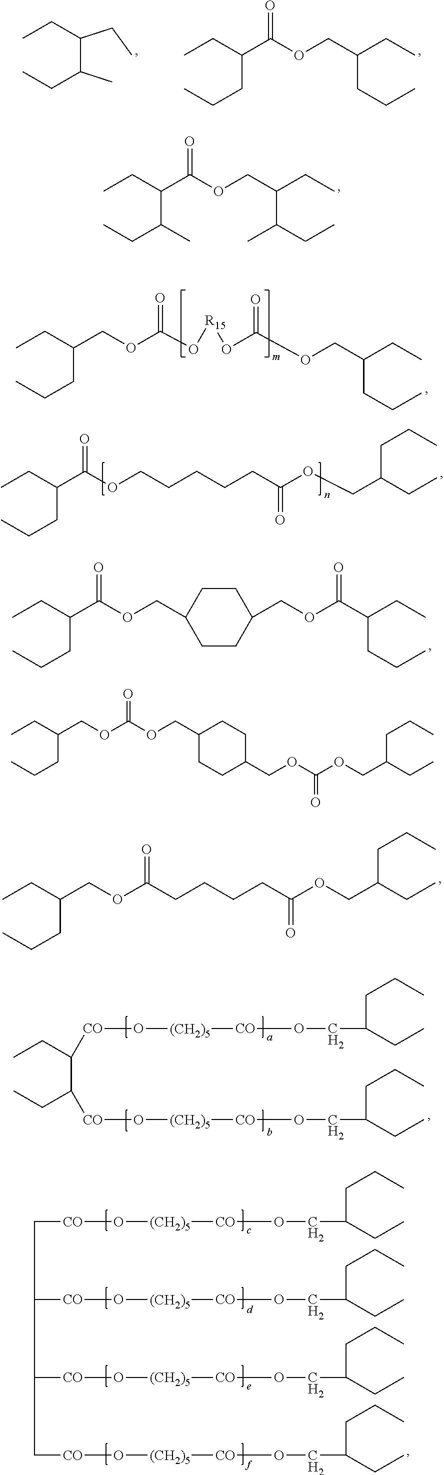

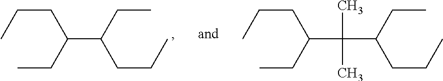

where R₁₅ is an alkyl chain having a carbon number of 2 to 18, the alkyl chain may be a straight chain, a branched chain, or a chain having cyclic skeleton, and

where each of m and n is independently integer number of to 30, and each of a, b, c, d, e and f is independently integer number of 0 to 30.).

(12) The resin composition according to the above (8), wherein the multifunctional epoxide is selected from the group comprising:

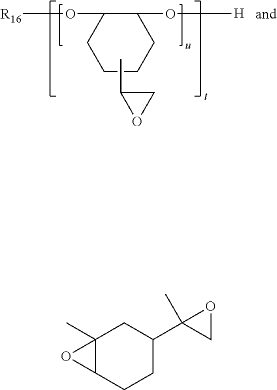

(where R₁₆ is an alkyl chain having a carbon number of 2 to 18, the alkyl chain may be a straight chain, a branched chain, or a chain having cyclic skeleton, and

where each of t and u is independently integer number of 1 to 30.)

(13) The resin composition according to the above (2), wherein at least one terminal of the aromatic polyamide is end-capped.

(14) The resin composition according to the above (1), wherein a total light transmittance of the layer in a sodium line (D line) is 40% or more.

(15) The resin composition according to the above (1), wherein the resin composition further contains an inorganic filler.

(16) A substrate used for forming an electronic element thereon, comprising:

a plate-like base member having a first surface and a second surface opposite to the first surface; and

an electronic element formation layer provided at a side of the first surface of the base member and configured to be capable of forming the electronic element on the electronic element formation layer,

wherein the electronic element formation layer contains a crystalline polymer and a haze value of the electronic element formation layer is 5% or more.

(17) The substrate according to the above (16), wherein a coefficient of thermal expansion (CTE) of the electronic element formation layer is 100 ppm/K or less.

(18) The substrate according to the above (16), wherein an average thickness of the electronic element formation layer is in the range of 1 to 50 μm.

(19) The substrate according to the above (16), wherein the electronic element is an organic EL element.

(20) A method of manufacturing an electronic device, comprising:

preparing a substrate, the substrate including,
a plate-like base member having a first surface and a second surface opposite to the first surface, and
an electronic element formation layer provided at a side of the first surface of the base member,
wherein the electronic element formation layer is used to form an electronic element on the electronic element formation layer and contains a crystalline polymer, and
wherein a haze value of the electronic element formation layer is 5% or more;

forming the electronic element on a surface of the electronic element formation layer opposite to the base member;

forming a cover layer so as to cover the electronic element;

irradiating the electronic element formation layer with light to thereby peel off the electronic element formation layer from the base member in an interface between the base member and the electronic element formation layer; and

separating the electronic device including the electronic element, the cover layer and the electronic element formation layer from the base member.

(21) The method according to the above (20), wherein a coefficient of thermal expansion (CTE) of the electronic element formation layer is 100 ppm/K or less.

(22) The method according to the above (20), wherein an average thickness of the electronic element formation layer is in the range of 1 to 50 μm.

(23) The method according to the above (20), wherein the crystalline polymer is an aromatic polyamide.

(24) The method according to the above (23), wherein the aromatic polyamide contains a carboxyl group.

(25) The method according to the above (23), wherein the aromatic polyamide contains a rigid structure in an amount of 85 mol % or more.

(26) An electronic device manufactured by using the method defined by the above (20).

According to the present invention, it is possible to form a layer by using the resin composition containing the crystalline polymer and the solvent dissolving the crystalline polymer, wherein a haze value of the layer is 5% or more. This layer formed by using the resin composition is used as the electronic element formation layer (substrate) provided in the electronic device. In the electronic device, the light emitted from the light emitting element passes through the electronic element formation layer and then is extracted outside the electronic device. By using the layer as the electronic element formation layer provided in the electronic device, it is possible to improve the light extraction efficiency of the light emitted from the light emitting element and extracted outside the electronic device.

### BRIEF DESCRIPTION OF THE DRAWINGS

FIG. 1 is a plan view which shows an embodiment of an organic electroluminescence illuminating device manufactured by applying a method of manufacturing an electronic device of the present invention.

FIG. 2 is a sectional view of the organic electroluminescence illuminating device shown in FIG. 1 which is taken along an A-A line of FIG. 1.

FIG. 3 is a sectional view which shows an embodiment of a sensor element manufactured by applying the method of manufacturing the electronic device of the present invention.

FIG. 4 is a vertical sectional view to illustrate the method of manufacturing the organic electroluminescence illuminating device shown in FIGS. 1 and 2 or the sensor element shown in FIG. 3 (method of manufacturing the electronic device of the present invention).

### MODE FOR CARRYING OUT THE INVENTION

Hereinafter, a resin composition, a substrate, a method of manufacturing an electronic device and an electronic device according to the present invention will be described in detail based on the preferred embodiments shown in the accompanying drawings.

First, prior to describing the resin composition, the substrate and the method of manufacturing the electronic device according to the present invention, description will be made on an organic electroluminescence illuminating device and a sensor element (organic EL illuminating device), which are manufactured by using the method of manufacturing the electronic device of the present invention. Namely, the organic electroluminescence illuminating device and the sensor element will be first described as examples the electronic device of the present invention.

<Organic EL Illuminating Device>

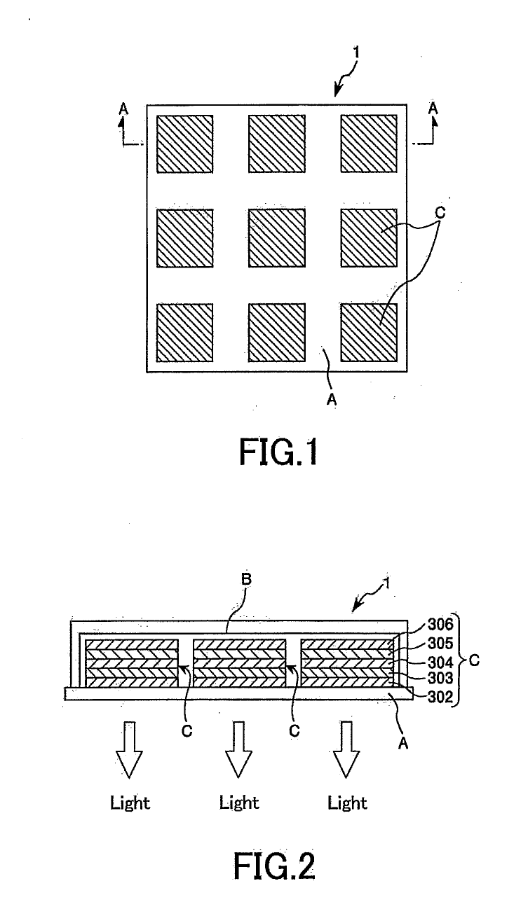

First, the organic electroluminescence illuminating device manufactured by applying the method of manufacturing the electronic device of the present invention will be described. FIG. 1 is a plan view which shows an embodiment of the organic electroluminescence illuminating device manufactured by applying the method of manufacturing the electronic device of the present invention. FIG. 2 is a sectional view of the organic electroluminescence illuminating device shown in FIG. 1 which is taken along an A-A line of FIG. 1. In the following description, the front side of paper in FIG. 1 will be referred to as “upper”, and the back side of paper in FIG. 1 will be referred to as “lower”, the upper side in FIG. 2 will be referred to as “upper”, and the lower side in FIG. 2 will be referred to as “lower”.

The organic EL illuminating device 1 shown in FIGS. 1 and 2 includes a resin film (electronic element formation layer) A formed of the resin composition of the present invention, a plurality of light emitting elements C and a sealing portion B.

In this organic EL illuminating device 1, a case, in which a closed space is formed, is constituted from the resin film A and the sealing portion B. Further, the light emitting elements C are provided inside the closed space of the case. By providing the light emitting elements C in the closed space of the case, it is possible to ensure airtightness with respect to the light emitting elements C, thereby enabling to prevent oxygen or moisture from penetrating to the light emitting elements C.

In this embodiment, there are nine light emitting elements (organic EL elements) C in the closed space of the case. Each of the light emitting elements C has a square shape in a planar view thereof. The nine light emitting elements C in the closed space are provided on the resin film A so as to be arranged at regular intervals in a reticular pattern (in a matrix pattern of 3×3).

As shown in FIG. 2, the organic EL illuminating device 1 having such a configuration can be considered as an illuminating device having a structure for extracting light emitted from the light emitting elements C from a side of the resin film A (through the resin film A).

As described above, the plurality of light emitting elements C are provided on the resin film (electronic element formation layer) A so as to form the reticular pattern.

In this embodiment, each of the light emitting elements C includes an anode 302, a cathode 306, a hole transport layer 303, an emission layer 304 and an electron transport layer 305. The anode 302 and the cathode 306 are provided so as to face each other. Further, the hole transport layer 303, the emission layer 304 and the electron transport layer 305 are laminated in this order from the anode 302 between the anode 302 and the cathode 306.

In the organic EL illuminating device 1 having such a configuration, the light emitted from the light emitting elements C passes through the resin film A and then is extracted outside the organic EL illuminating device 1. Namely, the light emitted from the light emitting elements C transmits out to the organic EL illuminating device 1 through the resin film A and then reaches to a targeted object. In this way, the targeted object is illuminated with the light. By appropriately combining the kind of light emitting materials and the like contained in the emission layers 304 of the respective light emitting elements C, it is possible to obtain the organic EL illuminating device 1 capable of emitting predetermined color.

<Sensor Element>

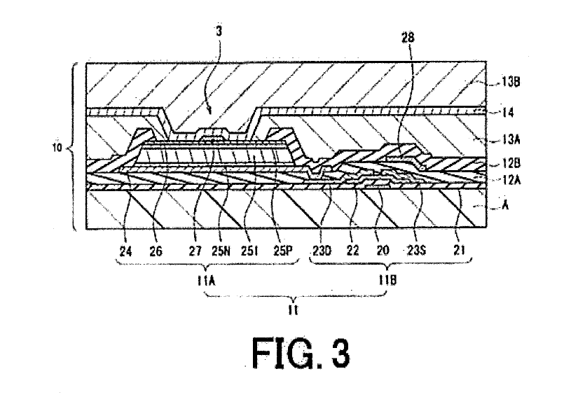

Next, the sensor element manufactured by applying the method of manufacturing the electronic device of the present invention will be described. FIG. 3 is a sectional view which shows an embodiment of the sensor element manufactured by applying the method of manufacturing the electronic device of the present invention. In the following description, the upper side in FIG. 3 will be referred to as “upper”, and the lower side in FIG. 3 will be referred to as “lower”.

The sensor element of the present invention is, for example, a sensor element that can be used in an input device. In one or plurality of embodiments of this discloser, the sensor element of the present invention is a sensor element including the resin film (electronic element formation layer) A formed of the resin composition of the present. In one or plurality of embodiments of this discloser, the sensor element of the present invention is a sensor element formed on the resin film A on the base member 500. In one or plurality of embodiments of this discloser, the sensor element of the present invention is a sensor element that can be peeled off from the base member 500.

Examples of the sensor element of the present invention includes an optical sensor element for capturing an image, an electromagnetic sensor element for sensing an electromagnetic wave, a radiation sensor element for sensing radiation such as X-rays, a magnetic sensor element for sensing a magnetic field, a capacitive sensor element for sensing a change of capacitance charge, a pressure sensor element for sensing a change of pressure, a touch sensor element and a piezoelectric sensor element.

Examples of the input device using the sensor element of the present invention includes a radiation (X-rays) imaging device using the radiation (X-rays) sensor element, a visible-light imaging device using the optical sensor element, a magnetic sensing device using the magnetic sensor element, a touch panel using the touch sensor element or the pressure sensor element, a finger authenticating device using the optical sensor element and a light emitting device using the piezoelectric sensor. The input device using the sensor element of the present invention may further have a function of an output device such as a displaying function and the like.

Hereinafter, an optical sensor element including a photodiode will be described as one example of the sensor element of the present invention.

A sensor element 10 shown in FIG. 3 includes the resin film (electronic element formation layer) A formed of the resin composition of the present invention and a plurality of pixel circuits 11 provided on the resin film A.

In this sensor element 10, each of the pixel circuits 11 includes a photodiode (photoelectric conversion element) 11A and a thin-film transistor (TFT) 11B serving as a driver element for the photodiode 11A. By sensing light passing through the resin film A with each of the photodiodes 11A, the sensor element 10 can serve as an optical sensor element.

On the resin film A, a gate insulating film 21 is provided. The gate insulating film 21 is constituted of a single layer film including any one of a silicon oxide (SiO₂) film, a silicon oxynitride (SiON) film and a silicon nitride (SiN) film; or a laminated film including two of more of these films. On the gate insulating film 21, a first interlayer insulating film 12A is provided. The first interlayer insulating film 12A is constituted of a silicon oxide film, a silicon nitride film or the like. This first interlayer insulating film 12A can also serve as a protective film (passivation film) to cover the top of the thin-film transistor 11B described below.

The photodiode 11A is formed on a selective region of the resin film A through the gate insulating film 21 and the first interlayer insulating film 12A. The photodiode 11A includes a lower electrode 24 formed on the first interlayer insulating film 12A, a n-type semiconductor layer 25N, an i-type semiconductor layer 25I, a p-type semiconductor layer 25P, an upper electrode 26 and a wiring layer 27. The lower electrode 24, the n-type semiconductor layer 25N, the i-type semiconductor layer 25I, the p-type semiconductor layer 25P, the upper electrode 26 and the wiring layer 27 are laminated from the side of the first interlayer insulating film 12A in this order.

The upper electrode 26 serves as an electrode for supplying, for example, a reference potential (bias potential) to a photoelectric conversion layer during a photoelectric conversion. The photoelectric conversion layer is constituted of the n-type semiconductor layer 25N, the i-type semiconductor layer 25I and the p-type semiconductor layer 25P. The upper electrode 26 is connected to the wiring layer 27 serving as a power supply wiring for supplying the reference potential. This upper electrode 26 is constituted of a transparent conductive film of ITO (indium tin oxide) or the like.

The thin-film transistor 11B is constituted of, for example, a field effect transistor (FET). The thin-film transistor 11B includes a gate electrode 20, a gate insulating film 21, a semiconductor film 22, a source electrode 23S and a drain electrode 23D.

The gate electrode 20 is formed of titanium (Ti), Al, Mo, tungsten (W), chromium (Cr) or the like and formed on the resin film A. The gate insulating film 21 is formed on the gate electrode 20. The semiconductor layer 22 has a channel region and is formed on the gate insulating film 21. The source electrode 23S and the drain electrode 23D are formed on the semiconductor film 22. In this embodiment, the drain electrode 23D is connected to the lower electrode 24 of the photodiode and the source electrode 23S is connected to a relay electrode 28 of the sensor element 10.

Further, in the sensor element 10 of this embodiment, a second interlayer insulating film 12B, a first flattened film 13A, a protective film 14 and a second flattened film 13B are laminated on the photodiode 11A and the thin-film transistor 11B in this order. Further, an opening 3 is formed on the first flattened film 13A so as to correspond to the vicinity of the selective region on which the photodiode 11A is formed.

In the sensor element 10 having such a configuration, the light transmitting from outside into the sensor element 10 passes through the resin film A and reaches to the photodiodes 11A. As a result, it is possible to sensor the light transmitting from outside into the sensor element 10.

(Method of Manufacturing Organic EL Illuminating Device 1 or Sensor Element 10)

The organic EL illuminating device 1 having the configuration as described above or the sensor element 10 having the configuration as described above can be manufactured by, for example, using the resin composition of the present invention as follows. That is, the organic EL illuminating device 1 or the sensor element 10 can be manufactured by using the method of manufacturing the electronic device of the present invention.

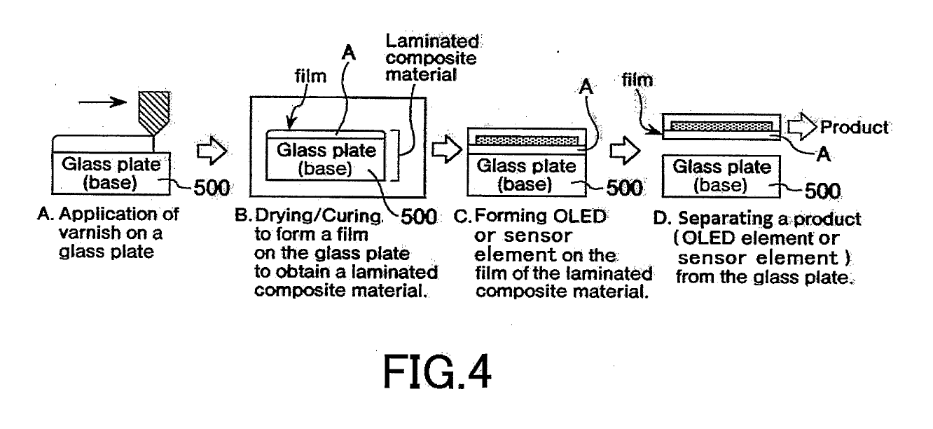

FIG. 4 is a vertical sectional view to illustrate the method of manufacturing the organic electroluminescence illuminating device shown in FIGS. 1 and 2 or the sensor element shown in FIG. 3 (method of manufacturing the electronic device of the present invention). In the following description, the upper side in FIG. 4 will be referred to as “upper”, and the lower side in FIG. 4 will be referred to as “lower”.

First, description will be made on the method of manufacturing the organic electroluminescence illuminating device 1 shown in FIGS. 1 and 2.

[1] First, the substrate (substrate of the present invention) is prepared. The substrate (substrate of the present invention) includes a plate-like base member 500 having a first surface and a second surface opposite to the first surface; and the resin film A. The resin film (electronic element formation layer) A is provided at a side of the first surface of the base member 500.

[1-A] First, the base member 500 having the first surface and the second surface, and having light transparency is prepared.

For example, glass, a metal, silicone, a resin or the like is used as a constituent material for the base member 500. These materials may be used alone or in combination of two or more as appropriate.

[1-B] Next, the resin film A is formed on the first surface (one surface) of the base member 500. As a result, the substrate including the base member 500 and the resin film A (laminated composite material in FIG. 3) is obtained.

The resin composition of the present invention is used to form the resin film A. The resin composition of the present invention contains a crystalline polymer and a solvent dissolving the crystalline polymer. By using such a resin composition, the resin film (electronic element formation layer) A containing the crystalline polymer is formed, wherein a haze value of the resin film A is 5% or more.

Examples of the method of forming the resin film A include a method in which the resin composition (varnish) is supplied on the first surface of the base member 500 by using a die coat method as shown in FIG. 4(A), and thereafter the resin composition is dried and heated (referred to FIG. 4(B)).

In this regard, it is to be noted that a method of supplying the resin composition on the first surface of the base member 500 is not limited to the die coat method. Various kinds of liquid-phase film formation methods such as an ink jet method, a spin coat method, a bar coat method, a roll coat method, a wire bar coat method and a dip coat method can be used as such a method.

Further, as described above, the resin composition of the present invention contains the crystalline polymer and the solvent dissolving the crystalline polymer. By using such a resin composition, it is possible to obtain the resin film A containing the crystalline polymer, wherein the haze value of the resin film A is 5% or more. This resin composition of the present invention will be described later.

In one or plurality of embodiments of this disclosure, in terms of suppression of curvature deformation and/or enhancement of dimension stability, a heating treatment is carried out to the resin film A under the temperature in the range from approximately +40° C. of a boiling point of the solvent to approximately +100° C. of the boiling point of the solvent, more preferably in the range from approximately +60° C. of the boiling point of the solvent to approximately +80° C. of the boiling point of the solvent, even more preferably at approximately +70° C. of the boiling point of the solvent. In one or plurality of embodiments of this disclosure, in terms of suppression of curvature deformation and/or enhancement of dimension stability, the temperature of the heating treatment in this step [1-B] is in the range of approximately 200 to 250° C. In one or plurality of embodiments of this disclosure, in terms of suppression of curvature deformation and/or enhancement of dimension stability, a heating time (duration) in this step [1-B] is in the range of more than approximately 1 minute but less than approximately 30 minutes.

Further, this step [1-B], in which the resin film A is formed on the base member 500, may include a step of curing the resin film A after drying and heating the resin composition. A temperature of curing the resin film A depends on performance of a heating apparatus, but is preferably in the range of 220 to 420° C., more preferably in the range of 280 to 400° C., further more preferably in the range of 330 to 370° C., and even more preferably in the range of 340 to 370° C. A time (duration) of curing the resin film A is in the range of 5 to 300 minutes or 30 to 240 minutes.

[2] Next, the nine (plurality of) light emitting elements (electronic elements) C are formed on the resin film A provided in the obtained substrate so as to form the reticular pattern.

[2-A] First, the anodes (individual electrodes) 302 are formed on the resin film A in the reticular pattern.

[2-B] Next, each of the hole transport layers 303 is formed on the corresponding anode 302 so as to cover it.

[2-C] Next, each of the emission layers 304 is formed on the corresponding hole transport layer 303 so as to cover it.

[2-D] Next, each of the electron transport layers 305 is formed on the corresponding emission layer 304 so as to cover it.

[2-E] Next, each of the cathodes 306 is formed on the corresponding electron transport layer 305 so as to cover it.

In this regard, each layer formed in the steps [2-A] to [2-E] can be formed by using a gas-phase film formation method such as a sputter method, a vacuum deposition method, a CVD method and the like or a liquid-phase film formation method such as an ink jet method, a spin coat method, a casting method and the like.

[3] Next, the sealing portion B is prepared. Then, the sealing portion B is provided on the resin film A so as to cover each of the light emitting elements C. In this way, the closed space of the case is formed by the resin film A and the sealing portion B. In the closed space, the light emitting elements C are sealed with the resin film A and the sealing portion B.

In this regard, the sealing with the resin film A and the sealing portion B as described above can be performed by interposing an adhesive between the resin film A and the sealing portion B and then drying the adhesive.

By carrying out the steps [1] to [3] as described above, the organic EL illuminating device 1 including the resin film A, the light emitting elements C and the sealing portion B is formed on the base member 500 (referred to FIG. 4(C)).

[4] Next, the resin film (electronic element formation layer) A is irradiated with light from a side of the base member 500.

By doing so, the resin film A is peeled off from the first surface of the base member 500 in an interface between the base member 500 and the resin film A.

As a result, the organic EL illuminating device (electronic device) 1 is separated from the base member 500 (referred to FIG. 4(D)).

The light to be irradiated to the resin film A is not particularly limited to a specific kind as long as the resin film A can be peeled off from the first surface of the base member 500 in the interface between the base member 500 and the resin film A by irradiating the resin film A with the light. The light is preferably laser light. By using the laser light, it is possible to reliably peel off the resin film A from the base member 500 in the interface between the base member 500 and the resin film A.

Further, examples of the laser light include an excimer laser of a pulse oscillator type or a continuous emission type, a carbon dioxide laser, a YAG laser and a YVO₄ laser.

By carrying out the steps [1] to [4] as described above, it is possible to obtain the organic EL illuminating device 1 peeled off from the base member 500.

Next, description will be made on the method of manufacturing the sensor element shown in FIG. 3.

[1] First, in the same manner as the method of manufacturing the organic electroluminescence illuminating device 1 shown in FIGS. 1 and 2, the substrate (substrate of the present invention) including the base member 500 and the resin film (electronic element formation layer) A formed on the base member 500 is prepared. Since a step for forming the resin film A on the base member 500 is identical to that of the method of manufacturing the organic electroluminescence illuminating device 1 described above, description to the step for forming the resin film A on the base member 500 is omitted here (referred to FIGS. 4(A) and 4(B)).

[2] Next, the sensor element 10 described above is formed on the resin film A provided in the obtained substrate. A method for forming the sensor element 10 on the resin film A is not particularly limited to a specific method. The formation of the sensor element 10 on the resin film A can be carried out with a known suitable method appropriately selected or modified for manufacturing a desired sensor element.

By carrying out the steps [1] to [2] as described above, the sensor element 10 including the resin film A, the pixel circuits 11 is formed on the base member 500 (referred to FIG. 4(C)).

[3] Next, the resin film (electronic element formation layer) A is irradiated with the light from the side of the base member 500 to peel off the sensor element (electronic device) 10 from the base member 500 (referred to FIG. 4(D)). Since a step for peeling off the sensor element from the base member 500 is identical to the above-mentioned step for peeling off the organic EL illuminating device 1 from the base member 500, description to the step for peeling off the sensor element 10 from the base member 500 is omitted here.

By carrying out the steps [1] to [3] as described above, it is possible to obtain the sensor element 10 peeled off from the base member 500.

In the organic EL illuminating device 1 having the structure as described above, if transparency of the resin film A becomes higher than necessary, light diffuseness of the resin film A becomes low. The deterioration of the light diffuseness of the resin film A causes a leak of the light through edges of the resin film A. Due to the leak of the light, there is a problem in that light extraction efficiency of the organic EL illuminating device 1 becomes low.

In the sensor element 10 having the configuration as described above, if transparency of the resin film A becomes higher than necessary, light diffuseness of the resin film A becomes low. The deterioration of the light diffuseness of the resin film A causes a leak of the light through edges of the resin film A. Due to the leak of the light, there is a problem in that light introduction efficiency of the sensor element 10 becomes low.

For the purpose of solving such a problem, in the present invention, the resin composition containing the crystalline polymer is used for forming the resin film (layer) A. By forming the resin film (layer) A with the resin composition containing the crystalline polymer, it is possible to set the haze value of the resin film (layer) A to be 5% or more. By setting the haze value of the resin film A to fall within the above range, it is possible to improve light diffuseness of the light emitted from the light emitting elements C and passing through the resin film A. The improvement of the light diffuseness of the resin film A makes it possible to reliably suppress or prevent the leak of the light through the edges of the resin film A, to thereby improve the light extraction efficiency of the above-mentioned organic EL illuminating device 1 and the light introduction efficiency of the sensor element 10.

As described above, the resin film A having the configuration as described above can be formed by using the resin composition of the present invention which contains the crystalline polymer and the solvent dissolving the crystalline polymer. Hereinafter, detailed description will be made on constituent materials contained in the resin composition of the present invention.

[Crystalline Polymer]

The crystalline polymer is used as a main material of the resin film (electronic element formation layer) A constituted of the resin composition. The crystalline polymer is contained in the resin composition in order to set the haze value of the resin film A to be 5% or more.

As described above, such a crystalline polymer is not particularly limited to a specific kind as long as it can set the haze value of the resin film A to be 5% or more. Examples of the crystalline polymer include an aromatic polyamide, a semi-aromatic polyamide and an alicyclic polyamide. These polymers may be used alone or in combination of two or more. Among them, the aromatic polyamide is preferably used as the crystalline polymer. By using the aromatic polyamide as the crystalline polymer, it is possible to easily set the haze value of the resin film A to be 5% or more. Further, it is also possible to efficiently perform the peeling-off of the resin film A in the interface between the base member 500 and the resin film A due to the irradiation of the light to the resin film A.

Regarding the aromatic polyamide, it is preferred that the aromatic polyamide is an aromatic polyamide containing one or more functional groups that can react with an epoxy group. Further, it is preferred that the aromatic polyamide containing one or more functional groups that can react with the epoxy group is an aromatic polyamide containing a carboxyl group. Since the aromatic polyamide contains the carboxyl group, it is possible to improve solvent resistance of the formed resin film A. By improving the solvent resistance of the resin film A, it is possible to expand the range of choices for a liquid material used when the light emitting devices C are formed on the resin film A.

Further, it is preferred that the aromatic polyamide is a wholly aromatic polyamide. By using the wholly aromatic polyamide as the crystalline polymer for the resin film A, it is possible to reliably set the haze value of the formed resin film A to fall within the above range. In this regard, it is to be noted that the wholly aromatic polyamide refers to that all of amide bonds included in a main chain of the aromatic polyamide are bonded to each other through the aromatic group (aromatic ring) without bonding to each other through a chain or cyclic aliphatic group.

In view of the foregoing, it is preferred that the aromatic polyamide has a repeating unit represented by the following general formula (I):

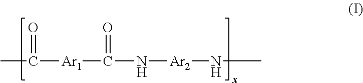

where x represents an integer of 1 or more; Ar₁ is represented by the following general formula (II) or (III):

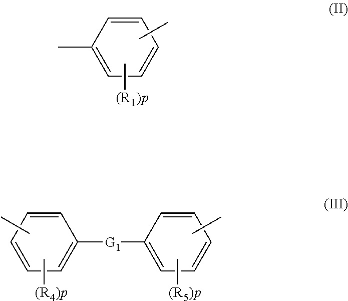

(where p=4; each of R₁, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).); and Ar₂ is represented by the following general formula (IV) or (V):

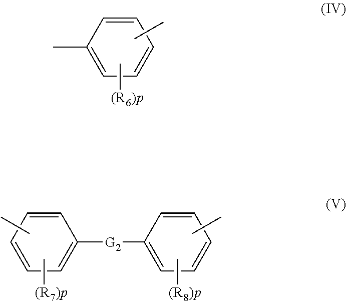

(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

Further, regarding the aromatic polyamide containing the carboxyl group, it is preferred that the aromatic polyamide containing the carboxyl group has a first repeating unit represented by the following general formula (VI) and a second repeating unit represented by the following general formula (VII):

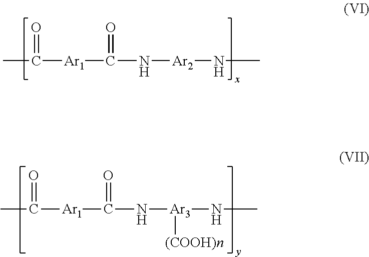

where x represents mol % of the first repeating unit, y represents mol % of the second repeating unit, n represents an integer number of 1 to 4, Ar₁ is represented by the following general formula (VIII) or (VIII′):

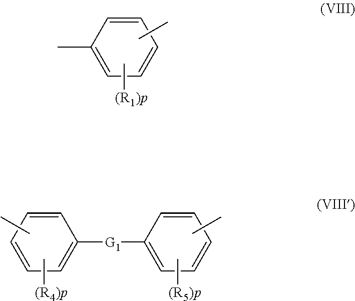

(where p=4; each of R₁, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), Ar₂ is represented by the following general formula (IX) or (X):

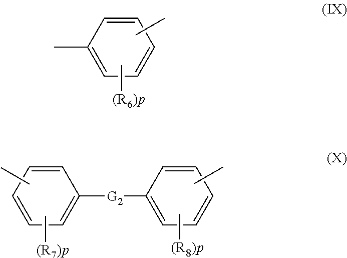

(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Ar₃ is represented by the following general formula (XI) or (XII):

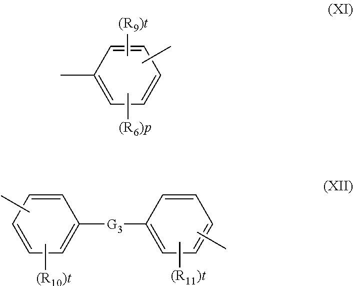

(where t=1 to 3; each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₃ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

Regarding the aromatic polyamide containing the carboxyl group, in one or plurality of embodiments of this disclosure, the general formulas (VI) and (VII) are selected so that the aromatic polyamide is soluble in a polar solvent or a mixed solvent containing one or more polar solvents. In one or plurality of embodiments of this disclosure, x in the general formula (VI) varies in the range of 90.0 to 99.99 mol %, and y in the general formula (VII) varies in the range of 10.0 to 0.01 mol %. In one or plurality of embodiments of this disclosure, x in the general formula (VI) varies in the range of 90.1 to 99.9 mol %, and y in the general formula (VII) varies in the range of 9.9 to 0.1 mol %. In one or plurality of embodiments of this disclosure, x in the general formula (VI) varies in the range of 90.0 to 99.0 mol %, and y in the general formula (VII) varies in the range of 10.0 to 1.0 mol %. In one or plurality of embodiments of this disclosure, x in the general formula (VI) varies in the range of 92.0 to 98.0 mol %, and y in the general formula (VII) varies in the range of 8.0 to 2.0 mol %. In one or plurality of embodiments of this disclosure, the aromatic polyamide contains the multiple repeat units represented with the general formulas (VI) and (VII) where Ar₁, Ar₂, and Ar₃ may be the same as or different from each other.

Further, the aromatic polyamide contains a rigid structure (rigid component) preferably in an amount of 85 mol % or more, and more preferably in an amount of 95 mol % or more. By setting the amount of the rigid structure in the aromatic polyamide to fall within the above range, it is possible to further improve crystallizability of the aromatic polyamide. This makes it possible to more reliably set the haze value of the resin film A to be 5 mol % or more.

In the present specification, the rigid structure refers to that a monomer component (repeating unit) constituting the aromatic polyamide has linearity in a main structure (skeleton) thereof. Specifically, the rigid structure is the repeating unit represented by the general formula (I), the general formula (VI) or the general formula (VII). Further, Ar₁ in the repeating unit represented by the general formula (I), the general formula (VI) or the general formula (VII) is represented by the following general formula (A) or (B):

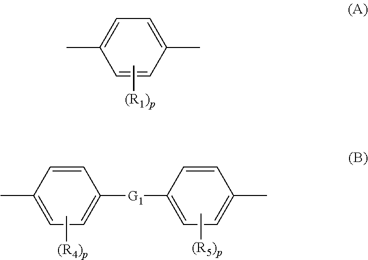

(where p=4; each of R₁, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Ar₂ in the repeating unit represented by the general formula (I) or the general formula (VI) is represented by the following general formula (C) or (D):

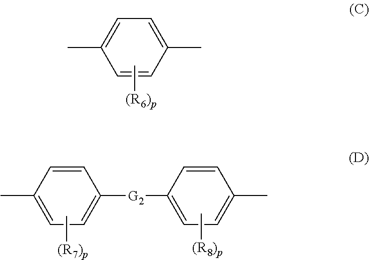

(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Ar₃ in the repeating unit represented by the general formula (VII) is represented by the following general formula (E) or (F):

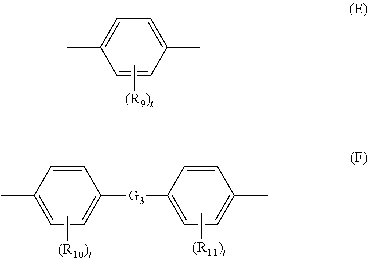

(where t=1 to 3; each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₃ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

Concrete examples of Ar₁ include a structure derived from terephthaloyl dichloride (TPC), concrete examples of Ar₂ include a structure derived from 4,4′-diamino-2,2′-bistrifluoromethyl benzidine (PFMB), and concrete examples of Ar₃ include a structure derived from a structure derived from 4,4′-diaminodiphenic acid (DADP) and a structure derived from 3,5-diaminobenzoic acid (DAB).

Further, a number average molecular weight (Mn) of the aromatic polyamide is preferably 6.0×10⁴ or more, more preferably 6.5×10⁴ or more, more preferably 7.0×10⁴ or more, further more preferably 7.5×10⁴ or more and even more preferably 8.0×10⁴ or more. Further, the number average molecular weight of the aromatic polyamide is preferably 1.0×10⁶ or less, more preferably 8.0×10⁵ or less, further more preferably 6.0×10⁵ or less, and even more preferably 4.0×10⁵ or less. By using the aromatic polyamide satisfying the above condition, it is possible for the resin film A to reliably provide a function as a foundation layer in the organic EL illuminating device 1 or the sensor element 10. Further, it is possible to reliably set the haze value of the resin film A to fall within the range described above.

In the present specification, the number average molecular weight (Mn) and a weight average molecular weight (Mw) of the polyamide are measured with a Gel Permeation Chromatography. Specifically, they are measured by using the method explained in the following Examples.

Further, molecular weight distribution of the aromatic polyamide (=Mw/Mn) is preferably 5.0 or less, more preferably 4.0 or less, more preferably 3.0 or less, further more preferably 2.8 or less, further more preferably 2.6 or less, and even more preferably 2.4 or less. Further, the molecular weight distribution of the aromatic polyamide is preferably 2.0 or more. By using the aromatic polyamide satisfying the above condition, it is possible for the resin film A to reliably provide the function as the foundation layer in the organic EL illuminating device 1 or the sensor element 10. Further, it is possible to reliably set the haze value of the resin film A to fall within the range described above.

It is preferred that the aromatic polyamide is obtained through a step of re-precipitating it after the aromatic polyamide is synthesized. By using the aromatic polyamide obtained through the step of re-precipitation, it is possible for the resin film A to reliably provide the function as the foundation layer in the organic EL illuminating device or the sensor element 10. Further, it is possible to reliably set the haze value of the resin film A to fall within the range described above.

In one or plurality of embodiments of this disclosure, one or both of a terminal —COOH group and a terminal —NH₂ group of the aromatic polyamide are end-capped. The end-capping of the terminals is preferable from the point of view of enhancement of heat resistance property of the polyamide film (namely, resin film A). The terminals of the polyamide can be end-capped by either the reaction of polymerized polyamide with benzoyl chloride in the case where the terminal of polyamide is —NH₂, or the reaction of polymerized polyamide with aniline in the case where the terminal of polyamide is —COOH. However, the method of end-capping is not limited to this method.

[Inorganic Filler]

The resin composition may contain an inorganic filler in addition to the crystalline polymer in an amount such that the resin film A is not broken when the resin film A is peeled off from the base member 500 in the above mentioned method of manufacturing the organic EL illuminating device 1 or the sensor element 10. By using the resin composition containing the inorganic filler, it is possible to reduce a coefficient of thermal expansion of the resin film A and to more reliably set the haze value of the resin film A to be 5% or more.

This inorganic filler is not particularly limited to a specific kind, but is preferably formed into a particle shape or is preferably constituted of a fiber.

Further, a constituent material for the inorganic filler is not particularly limited to a specific material as long as it is an inorganic material. Examples of such a constituent material for the inorganic filler include a metal oxide such as silica, alumina and a titanium oxide; a mineral such as mica; glass; and a mixture of them. These materials may be used singly or in combination of two or more of them. In this regard, examples of a kind of glass include E glass, C glass, A glass, S glass, D glass, NE glass, T glass, low permittivity glass and high permittivity glass.

In the case where the inorganic filler is constituted of the fiber, an average fiber diameter of the fiber is preferably in the range of 1 to 1000 nm. By using the resin composition containing the inorganic filler having the above average fiber diameter, it is possible for the resin film A to reliably provide the function as the foundation layer in the organic EL illuminating device 1 or the sensor element 10. Further, it is possible to reliably set the haze value of the resin film A to fall within the range described above.

Here, the fiber may be formed of single fibers. The single fibers included therein are arranged without paralleling with each other and to be sufficiently spaced apart from each other so that a liquid precursor of a matrix resin enters among the single fibers. In this case, the average fiber diameter corresponds to an average diameter of the single fibers. Further, the fiber may constitute one line of thread in which a plurality of single fibers is bundled. In this case, the average fiber diameter is defined as an average value of a diameter of the one line of thread. Specifically, the average fiber diameter is measured by the method explained in the Examples. Further, from the point of view of improving the transparency of the film, the average fiber diameter of the fiber is preferably small. Further, a refractive index of the crystalline polymer included in the resin composition (crystalline polymer solution) and a refractive index of the inorganic filler are preferably close to each other. For example, in the case where a difference of refractive indexes of a material to be used as the fiber and the crystalline polymer in the wavelength of 589 nm is 0.01 or less, it becomes possible to form a film having high transparency regardless of the fiber diameter. Further, examples of a method of measuring the average fiber diameter include a method of observing the fiber with an electronic microscope.

Further, in the case where the inorganic filler is formed into the particle shape, an average particle size of the particles is preferably in the range of 1 to 1000 nm. By using the resin film A containing the inorganic filler in the form of the particle shape having the above average particle size, it is possible for the resin film A to reliably provide the function as the foundation layer in the organic EL illuminating device 1 or the sensor element 10. Further, it is possible to reliably set the haze value of the resin film A to fall within the range described above.

Here, the average particle size of the particles refers to a diameter corresponding to an average projection circle. Specifically, the average particle size of the particles is measured by the method explained in the Examples.

A shape of each of the particles is not particularly limited to a specific shape. Examples of such a shape include a spherical shape, a perfect spherical shape, a rod shape, a plate shape and a combined shape of them. By using the inorganic filler having such a shape, it is possible to reliably set the haze value of the resin film A to fall within the range described above.

Further, the average particle size of the particles is preferably small. Further, the refractive index of the crystalline polymer included in the resin composition (crystalline polymer solution) and the refractive index of the inorganic filler are preferably close to each other. This makes it possible to further improve the transparency of the resin film A. For example, in the case where a difference of refractive indexes of the material to be used as the particles and the crystalline polymer in the wavelength of 589 nm is 0.01 or less, it becomes possible to form the resin film A having high transparency regardless of the particle size. Further, examples of a method of measuring the average particle size include a method of measuring the average particle size with a particle size analyzer.

A ratio of the inorganic filler in a solid matter contained in the resin composition (crystalline polymer solution) is not particularly limited to a specific value, but is preferably in the range of 1 to 50 volume %, more preferably in the range of 2 to 40 volume %, and even more preferably in the range of 3 to 30 volume %. On the other hand, a ratio of the crystalline polymer in the solid matter contained in the resin composition (crystalline polymer solution) is not particularly limited to a specific value, but is preferably in the range of 50 to 99 volume %, more preferably in the range of 60 to 98 volume %, and even more preferably in the range of 70 to 97 volume %.

In this regard, it is to be noted that the “solid matter” refers to a component other than the solvent contained in the resin composition in this specification. A volume conversion of the solid matter, a volume conversion of the inorganic filler and/or a volume conversion of the crystalline polymer can be calculated from each component usage at the time of preparing the crystalline polymer solution. Alternatively, they can be also calculated by removing the solvent from the crystalline polymer solution.

[Epoxy Reagent]

Furthermore, the resin composition may contain an epoxy reagent in addition to the crystalline polymer for promoting the curing of the resin composition in the above mentioned method of manufacturing the organic EL illuminating device 1 or the sensor element 10, if needed. It is preferred that the epoxy reagent added into the resin composition is a multifunctional epoxide.

In one or plurality of embodiments of this disclosure, the multifunctional epoxide is an epoxide containing two or more glycidyl epoxy groups, or an epoxide containing two or more alicyclic groups.

In one or plurality of embodiments of this disclosure, the multifunctional epoxide is selected from the group with general structures (α) and (β):

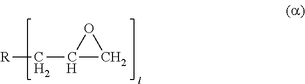

(where 1 represents the number of glycidyl group, and R is selected from the group comprising:

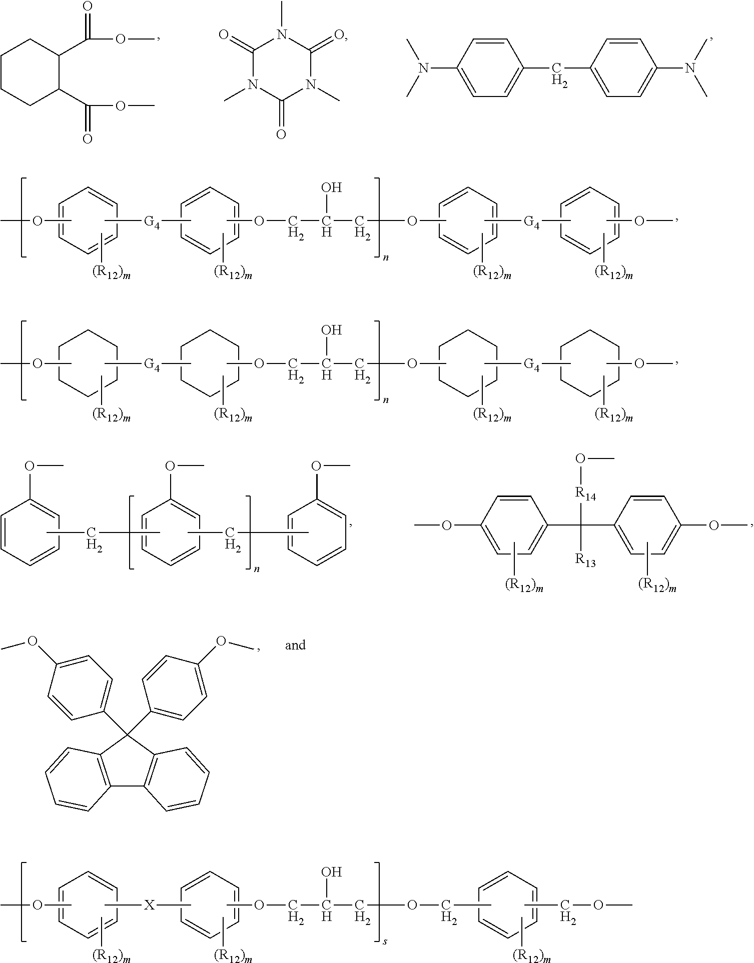

where m=1 to 4, and n and s are the average number of units and independently range from of 0 to 30;

where each of R₁₂ is same or different, and selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₄ is selected from the group consisting of a covalent bond, a CH₂ group, a C(CH₃)₂ group, a C(CF₃)₂ group, a C(CX₃)₂ group (X represents a halogen atom); a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group, R₁₃ is a hydrogen or methyl group, and R₁₄ is a divalent organic group.))

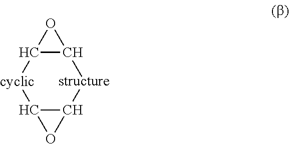

(where the cyclic structure is selected from the group comprising:

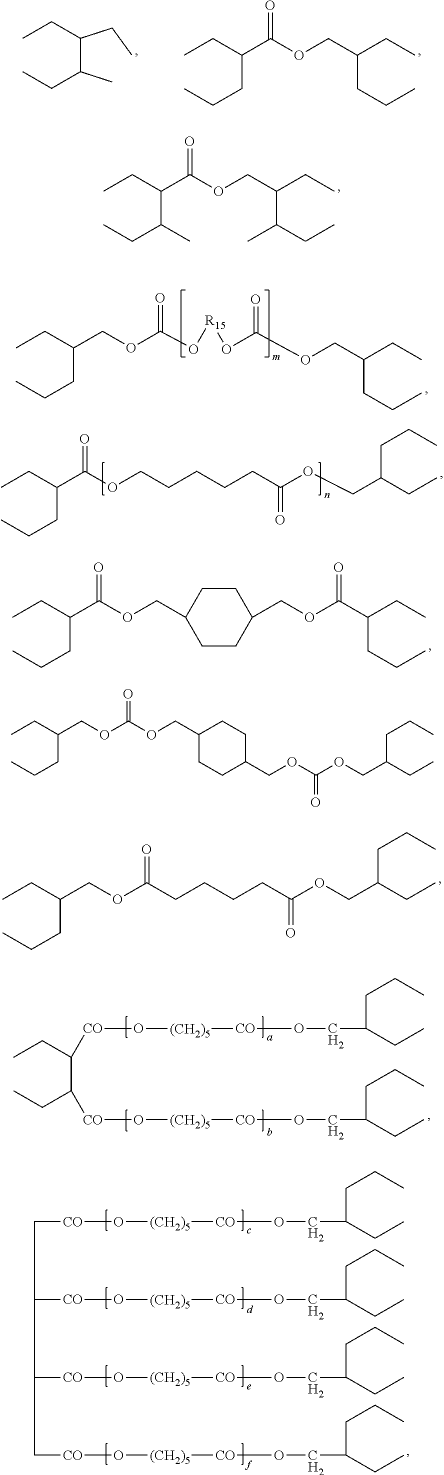

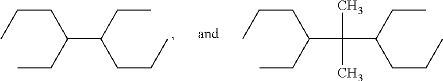

where R₁₅ is an alkyl chain having a carbon number of 2 to 18, the alkyl chain may be a straight chain, a branched chain, or a chain having cyclic skeleton, and

where each of m and n is independently integer number of 1 to 30, and each of a, b, c, d, e and f is independently integer number of 0 to 30.).

In one or plurality of embodiments of this disclosure, the multifunctional epoxide is selected from the group comprising:

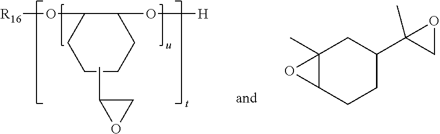

(where R₁₆ is an alkyl chain having a carbon number of 2 to 18, the alkyl chain may be a straight chain, a branched chain, or a chain having cyclic skeleton, and

where each of t and u is independently integer number of 1 to 30.).

[Other Components]

Furthermore, the resin composition may contain an antioxidant, an ultraviolet absorbing agent, a dye, a pigment, a filler such as another inorganic filler and the like, if needed, in the degrees to which the function of the foundation layer in the organic EL illuminating device 1 or the sensor element 10 is not impaired and the haze value of the resin film A is set to fall within the range described above.

[Amount of Solid Matter]

A ratio of the solid matter contained in the resin composition is preferably 1 volume % or more, more preferably 2 volume % or more, and even more preferably 3 volume % or more. Further, the ratio of the solid matter contained in the resin composition is preferably 40 volume % or less, more preferably volume % or less, and even more preferably 20 volume % or less. By setting the ratio of the solid matter contained in the resin composition to fall within the above range, it is possible for the resin film A to reliably provide the function as the foundation layer in the organic EL illuminating device or the sensor element 10. Further, it is possible to reliably set the haze value of the resin film A to fall within the range described above.

[Solvent]

One to be able to solve the crystalline polymer is used as the solvent, which is used to prepare a varnish (liquid material) containing the resin composition.

In one or plurality of embodiments of this disclosure, in terms of enhancement of solubility of the crystalline polymer to the solvent, the solvent is preferably a polar solvent or a mixed solvent containing one or more polar solvents. In one or plurality of embodiments of this disclosure, in terms of enhancement of solubility of the crystalline polymer to the solvent and enhancement of the adhesion between the resin film A and the base member, the solvent is preferably cresol; N,N-dimethyl acetamide (DMAc); N-methyl-2-pyrrolidinone (NMP); dimethyl sulfoxide (DMSO); 1,3-dimethyl-imidazolidinone (DMI); N,N-dimethyl formamide (DMF); butyl cellosolve (BCS); γ-butyrolactone (GBL) or a mixed solvent containing at least one of cresol, N,N-dimethyl acetamide (DMAc), N-methyl-2-pyrrolidinone (NMP), dimethyl sulfoxide (DMSO), 1,3-dimethyl-imidazolidinone (DMI), N,N-dimethyl formamide (DMF), butyl cellosolve (BCS) and γ-butyrolactone (GBL); a combination thereof or a mixed solvent containing at least one of the polar solvent thereof.

[Method of Manufacturing Resin Composition]

The resin composition as described above can be manufactured by, for example, using a manufacturing method including the following steps (a) to (e).

Hereinafter, description will be made on a case where the aromatic polyamide containing at least one functional group that can react with the epoxy group is used as the crystalline polymer and the resin composition contains the inorganic filler.

However, the resin composition of the present invention is not limited to a resin composition manufactured by using the following manufacturing method.

The step (a) is carried out for obtaining a mixture by dissolving at least one aromatic diamine in a solvent. The step (b) is carried out for obtaining free hydrochloric acid and a polyamide solution by reacting the at least one aromatic diamine with at least one aromatic dicarboxylic acid dichloride in the mixture. The step (c) is carried out for removing the free hydrochloric acid in the mixture by reaction with a trapping reagent. The step (d) is carried out for adding the inorganic filler to the mixture. The step (e) is an optional step and carried out for adding the multifunctional epoxide to the mixture.

In one or more embodiments of the method for manufacturing the polyamide solution of this disclosure, examples of the aromatic dicarboxylic acid dichloride include compounds represented by the following general formulas (XIII) and (XIV):

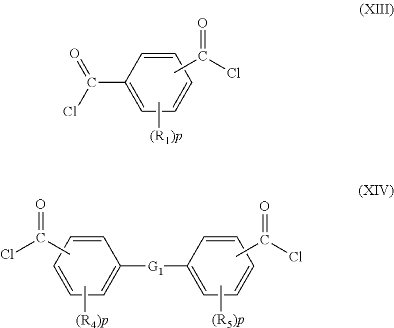

(where p=4; each of R₁, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

Specifically, examples of the aromatic dicarboxylic acid dichloride as described above include the following compounds.

Terephthaloyl dichloride (TPC)

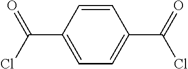 [SMILES: O=C(Cl)c1ccc(C(=O)Cl)cc1]

Isophthaloyl dichloride (IPC)

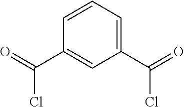 [SMILES: O=C(Cl)c1cccc(C(=O)Cl)c1]

4,4′-biphenyldicarbonyl dichloride (BPDC)

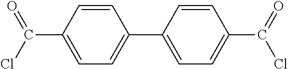 [SMILES: O=C(Cl)c1ccc(-c2ccc(C(=O)Cl)cc2)cc1]

In one or more embodiments of the method for manufacturing the polyamide solution of this disclosure, examples of the aromatic diamine include compounds represented by the following general formulas (XV) to (XVIII):

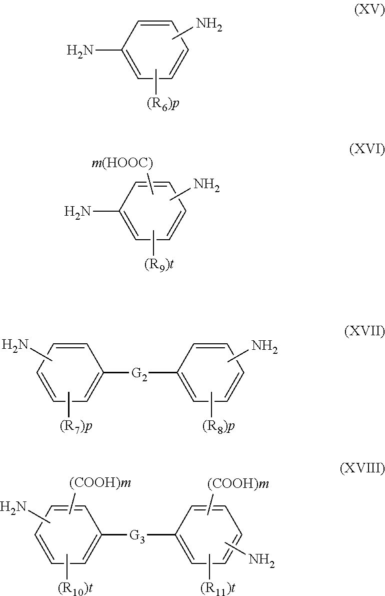

where p=4, m=1 or 2, and t=1 to 3, and where each of R₆, R₇, R₈, R₉, R₁₀ and R₁₁ is selected from the group consisting of a hydrogen atom, a halogen atom (a fluorine atom, a chlorine atom, a bromine atom, and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and combinations thereof, each R₆ is the same or different, each R₇ is the same or different, each R₈ is the same or different, each R₉ is the same or different, each R₁₀ is the same or different, each R₁₁ is the same or different, and each of G₂ and G₃ is selected from the group consisting of a covalent bond, a CH₂ group, a C(CH₃)₂ group, a C(CF₃)₂ group, a C(CX₃)₂ group (X represents a halogen atom.), a CO group, an O atom, an S atom, an SO₂ group, an Si (CH₃)₂ group, a 9,9-fluorene group, a substituted 9,9-fluorene group, and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

Specifically, examples of the aromatic diamine as described above include the following compounds.

4,4′-diamino-2,2′-bistrifluoromethyl benzidine (PFMB)

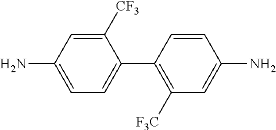 [SMILES: Nc1ccc(-c2ccc(N)cc2C(F)(F)F)c(C(F)(F)F)c1]

9,9-bis(4-aminophenyl) fluorine (FDA)

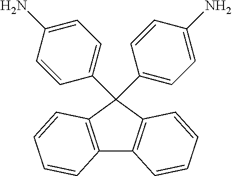 [SMILES: Nc1ccc(C2(c3ccc(N)cc3)c3ccccc3-c3ccccc32)cc1]

9,9-bis(3-fluoro-4-aminophenyl) fluorine (FFDA)

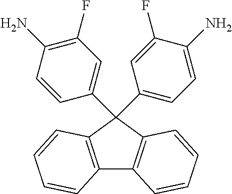 [SMILES: Nc1ccc(C2(c3ccc(N)c(F)c3)c3ccccc3-c3ccccc32)cc1F]

4,4′-diaminodiphenic acid (DADP)

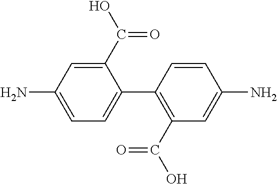 [SMILES: Nc1ccc(-c2ccc(N)cc2C(=O)O)c(C(=O)O)c1]

3,5-diaminobenzoic acid (DAB)

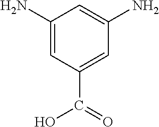 [SMILES: Nc1cc(N)cc(C(=O)O)c1]

4,4′-diamino-2,2′-bistrifluoromethoxyl benzidine (PFMOB)

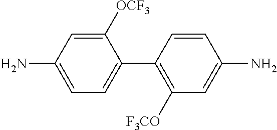 [SMILES: Nc1ccc(-c2ccc(N)cc2OC(F)(F)F)c(OC(F)(F)F)c1]

4,4′-diamino-2,2′-bistrifluoromethyl diphenyl ether (6FODA)

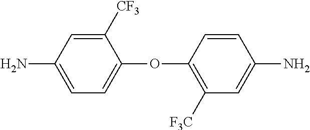 [SMILES: Nc1ccc(Oc2ccc(N)cc2C(F)(F)F)c(C(F)(F)F)c1]

Bis(4-amino-2-trifluoromethyl phenyloxyl)benzene (6FOQDA)

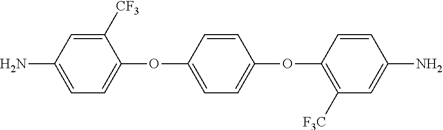 [SMILES: Nc1ccc(Oc2ccc(Oc3ccc(N)cc3C(F)(F)F)cc2)c(C(F)(F)F)c1]

Bis(4-amino-2-trifluoromethyl phenyloxyl)biphenyl (6FOBDA)

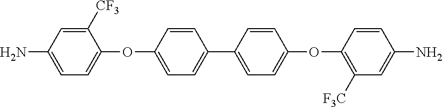 [SMILES: Nc1ccc(Oc2ccc(-c3ccc(Oc4ccc(N)cc4C(F)(F)F)cc3)cc2)c(C(F)(F)F)c1]

4,4′-diaminodiphenyl sulfone (DDS)

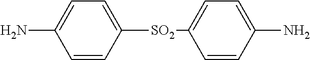 [SMILES: Nc1ccc(S(=O)(=O)c2ccc(N)cc2)cc1]

Regarding the diaminodiphenyl sulfone (DDS), the diaminodiphenyl sulfone may be 4,4′-diaminodiphenyl sulfone as expressed by the above formula, 3,3′-diaminodiphenyl sulfone or 2,2′-diaminodiphenyl sulfone.

In one or more embodiments of the method for manufacturing the polyamide solution of this disclosure, the functional groups that can react with the epoxy group is greater than approximately 1 mol % to and less than approximately 10 mol % of the total diamine mixture. In one or more embodiments of the method for manufacturing the polyamide solution of this disclosure, the functional group of the aromatic diamine containing the functional group that can react with the epoxy group is a carboxyl group. In one or more embodiments of the method for manufacturing the polyamide solution of this disclosure, one of the diamines is 4,4′-diaminodiphenic acid or 3,5-diaminobenzoic acid. In one or more embodiments of the method for manufacturing the polyamide solution of this disclosure, the functional group of the aromatic diamine containing the functional group that can react with the epoxy group is a hydroxyl group.

In one or more embodiments of the method for manufacturing the polyamide solution of this disclosure, the polyamide is prepared via a condensation polymerization in a solvent, where hydrochloric acid generated in the reaction is trapped by a reagent such as propylene oxide (PrO).

In one or plurality of embodiments of this disclosure, in terms of use of the polyamide solution in the method, the reaction of hydrochloric acid with the trapping reagent yields a volatile product.

In one or plurality of embodiments of this disclosure, in terms of use of the polyamide solution in the method, the trapping reagent is propylene oxide. In one or plurality of embodiments of this disclosure, the trapping reagent is added to the mixture before or during the step (c). By adding the reagent before or during the step (c), it is possible to reduce a degree of viscosity and generation of condensation in the mixture after the step (c), and thereby improving productivity of the polyamide solution. These effects become especially remarkable when the reagent is an organic reagent such as propylene oxide.

In one or plurality of embodiments of this disclosure, in terms of enhancement of heat resistance property of the resin film A, the method further includes a step of end-capping one or both of the terminal —COOH group and the terminal —NH₂ group of the polyamide. The terminals of the polyamide can be end-capped by either the reaction of polymerized polyamide with benzoyl chloride in the case where the terminal of polyamide is —NH₂, or the reaction of polymerized polyamide with aniline in the case where the terminal of polyamide is —COOH. However, the method of end-capping is not limited to this method.

In one or plurality of embodiments of this disclosure, the multifunctional epoxide is selected from the group of phenolic epoxides and cyclic aliphatic epoxides. In one or plurality of embodiments of this disclosure, the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, octahydro-2H-indeno[1,2-b:5,6-b′]bisoxylene, and epoxycyclohexylmethyl 3,4-epoxycyclohexanecarboxylate. In one or plurality of embodiments of this disclosure, the amount of multifunctional epoxide is in the range of approximately 2 to 10% of the weight of the polyamide.

In one or plurality of embodiments of this disclosure, in terms of use of the polyamide solution in the method, the polyamide is first isolated from the polyamide solution by re-precipitation and re-dissolution in a solvent prior to the addition of the inorganic filler and/or the multifunctional epoxide.

A re-precipitation can be carried out by a known method. In one or plurality of embodiments of this disclosure, the re-precipitation can be carried out by precipitating the polyamide by adding it to, for example, methanol, ethanol, isopropyl alcohol or the like; washing the polyamide; and re-dissolving the polyamide to the solvent.

The solvent described above can be used as a solvent for producing the crystalline polymer solution.

In one or plurality of embodiments of this disclosure, in terms of use of the polyamide solution in the method, the solution is produced so that the solution contains no inorganic salts.

By taking the steps as described above, the resin composition can be manufactured.

Further, the resin film A formed by using the resin composition obtained through the steps described above contains the crystalline polymer. Thus, the haze value of the resin film A can be preferably set to be 5% or more. In particular, the haze value of the resin film A is preferably in the range of 10 to 90%, more preferably in the range of 30 to 85%, and even more preferably in the range of 50 to 80%. By setting the haze value of the resin film A to fall within the above range, it is possible to further improve the light extraction efficiency of the light passing through the resin film A.

Furthermore, a total light transmittance of the resin film A, which is formed by using the resin composition, in a sodium line (D line) is set to preferably 40% or more, more preferably 45% or more, further more preferably 50% or more, and even more preferably 60% or more. By setting the total light transmittance of the resin film A to fall within the above range, the resin film A can have excellent light extraction efficiency. According to the present invention, since the crystalline polymer is contained in the resin film A, it is possible to easily obtain the resin film A having the total light transmittance falling within such an above range.

A retardation (Rth) of the resin film A in the wavelength of 400 nm in a thickness direction thereof is preferably 200.0 nm or less, more preferably 190.0 nm or less, further more preferably 180.0 nm or less, further more preferably 175.0 nm or less, and even more preferably 173.0 nm or less. In this regard, it is to be noted that the Rth of the resin film (crystalline polymer film) A can be obtained with a phase difference measurement device.

A coefficient of thermal expansion (CTE) of the resin film A is preferably 100.0 ppm/K or less, more preferably 80 ppm/K or less, further more preferably 60 ppm/K or less, and even more preferably 40 ppm/K or less. In this regard, it is to be noted that the CTE of the resin film A can be obtained with a thermal mechanical analyzer (TMA).

By respectively setting the Rth and the CTE of the resin film A to fall within the ranges described above, it is possible to reliably suppress or prevent warpage in the substrate including the base member 500 and the resin film A. Therefore, it is possible to improve a yield ratio of the organic EL illuminating device 1 or the sensor element 10 obtained by using such a substrate.

In the case where the resin film A contains the inorganic filler, an amount of the inorganic filler contained in the resin film A is preferably in the range of 1 to 50 volume %, more preferably in the range of 2 to 40 volume %, and even more preferably in the range of 3 to 30 volume %, with respect to the volume of the resin film A. By adding the inorganic filler to the resin film A in the above amount, it is possible to easily set the haze value, the Rth and the CTE of the resin film A to fall within the ranges described above. In this regard, a volume conversion of the resin film A and/or a volume conversion of the inorganic filler can be respectively calculated from component usages at the time of preparing the resin composition or they can be also obtained by measuring the volume of the resin film A.

Further, an average thickness of the resin film A is not particularly limited a specific value, but is preferably 50 μm or less, more preferably 30 μm or less, and even more preferably 20 μm or less. In addition, the average thickness is preferably 1 μm or more, more preferably 2 μm or more, and even more preferably 3 μm or more. By using the resin film A having the above average thickness, it is possible for the resin film A to reliably provide the function as the foundation layer in the organic EL illuminating device 1 or the sensor element 10. Further, it is possible to reliably suppress or prevent cracks from generating in the resin film A.

The shape of the light emitting element C (light emitting area) in the planar view thereof is the square shape in this embodiment, but is not limited thereto. It may be an arbitrary shape such as a polygonal shape (e.g., a triangular shape, a hexagonal shape) and a round shape (e.g., an exact circular shape, an elliptical shape).

Although the descriptions have been made on the resin composition, the substrate, the method of manufacturing the electronic device and the electronic device of the present invention based on the embodiments, the present invention is not limited thereto.

For example, in the resin composition and the substrate of the present invention, each component may be replaced with an arbitrary one capable of providing the same function. Alternatively, an arbitrary component may be added to them.

Further, in the method of manufacturing the electronic device of the present invention, one or more steps may be further added for the arbitrary purpose.

Further, in the above embodiments, the method of manufacturing the electronic device of the present invention is used to manufacture the organic EL illuminating device including the organic EL element as the light emitting element and the sensor element including the photodiode. However, the method of manufacturing the electronic device of the present invention is not limited thereto. For example, the method of manufacturing the electronic device of the present invention may be used to not only manufacture other illuminating devices such as a light emitting diode illuminating device including a light emitting diode as the light emitting element, but also manufacture various kinds of electronic devices such as an input device including a sensor element as the electronic element, a display device including a display element as the electronic element, an optical device including an optical element as the electronic element and a solar cell including a photoelectric conversion element as the electronic element.

### EXAMPLES

Hereinafter, the present invention will be described based on specific examples in detail.

1. Preparation of Resin Composition and Formation of Resin Film

### Example 1

[Preparation of Resin Composition]

<1> PFMB (3.2024 g, 0.01 mol) and DMAc (30 ml) were added to a 250 ml three necked round bottom flask, which is equipped with a mechanical stirrer, a nitrogen inlet and outlet, in order to obtain a solution.

<2> After the PFMB was completely dissolved in the solution, PrO (1.4 g, 0.024 mol) was added to the solution. Then, the solution was cooled to 0° C.

<3> Under stirring, TPC (2.015 g, 0.00950 mol) and IPC (0.106 g, 0.00050 mol) were added to the solution, and then the flask wall was washed with DMAc (1.5 ml).

<4> After two hours, benzoyl chloride (0.032 g, 0.23 mmol) was added to the solution and stirred for more two hours.

[Formation of Resin Film (Polyamide Film)]

A resin film was formed on a glass substrate by using the prepared resin composition.

That is, first, the resin composition was applied onto a flat glass substrate (10 cm×10 cm, “EAGLE XG” produced by Corning Inc., U.S.A.) with a spin coat method.

Next, the resin composition was dried at a temperature of 60° C. for 30 minutes or more to obtain a film. Thereafter, the temperature was raised from 60° C. to 350° C. The film was subjected to a curing treatment by keeping the temperature of 350° C. for 30 minutes under vacuum atmosphere or inert atmosphere. By doing so, a resin film was formed on the glass substrate.

In this regard, a thickness of the resin film was 23 μm.

### Example 2

A resin film of the Example 2 was formed on the glass substrate in the same manner as the Example 1, except that a thickness of the resin film to be formed on the glass substrate was changed to 14 μm in the forming the resin film (polyamide film).

### Example 3

A resin film of the Example 3 was formed on the glass substrate in the same manner as the Example 1, except that a thickness of the resin film to be formed on the glass substrate was changed to 8 μm in the forming the resin film (polyamide film).

### Example 4

A resin composition of the Example 4 was prepared in the same manner as the Example 1, except that the combination of TPC and IPC was changed to a combination of TPC (1.909 g, 0.00900 mol) and IPC (0.212 g, 0.00100 mol) as the dichloride component used in the step <3>. Thereafter, a resin film of the Example 4 was formed on the glass substrate by using the resin composition in the same manner as the Example 1.

In this regard, a thickness of the obtained resin film was 25 μm.

### Example 5

A resin film of the Example 5 was formed on the glass substrate in the same manner as the Example 4, except that a thickness of the resin film to be formed on the glass substrate was changed to 15 μm in the forming the resin film (polyamide film).

### Example 6

A resin film of the Example 6 was formed on the glass substrate in the same manner as the Example 4, except that a thickness of the resin film to be formed on the glass substrate was changed to 8 μm in the forming the resin film (polyamide film).

### Example 7

A resin composition of the Example 7 was prepared in the same manner as the Example 1, except that the combination of TPC and IPC was changed to a combination of TPC (1.697 g, 0.00800 mol) and IPC (0.424 g, 0.00200 mol) as the dichloride component used in the step <3>. Thereafter, a resin film of the Example 7 was formed on the glass substrate by using the resin composition in the same manner as the Example 1.

In this regard, a thickness of the obtained resin film was 23 μm.

### Example 8

A resin film of the Example 8 was formed on the glass substrate in the same manner as the Example 7, except that a thickness of the resin film to be formed on the glass substrate was changed to 18 μm in the forming the resin film (polyamide film).

### Example 9

A resin composition of the Example 9 was prepared in the same manner as the Example 1, except that the combination of PFMB and DMAc was changed to a combination of PFMB (3.042 g, 0.0095 mol), DAB (0.0761 g, 0.0005 mol) and DMAc (30 ml) in the step <1> and the combination of TPC and IPC was changed to TPC (2.121 g, 0.01000 mol) as the dichloride component used in the step <3>. Thereafter, a resin film of the Example 3 was formed on the glass substrate by using the resin composition in the same manner as the Example 1.

In this regard, a thickness of the obtained resin film was 25 μm.

### Example 10

A resin film of the Example 10 was formed on the glass substrate in the same manner as the Example 9, except that a thickness of the resin film to be formed on the glass substrate was changed to 15 μm in the forming the resin film (polyamide film).

### Example 11

A resin film of the Example 11 was formed on the glass substrate in the same manner as the Example 9, except that a thickness of the resin film to be formed on the glass substrate was changed to 7 μm in the forming the resin film (polyamide film).

### Example 12

A resin composition of the Example 12 was prepared in the same manner as the Example 9, except that TPC was changed to a combination of TPC (2.015 g, 0.00950 mol) and IPC (0.106 g, 0.00050 mol) as the dichloride component used in the step <3>. Thereafter, a resin film of the Example 12 was formed on the glass substrate by using the resin composition in the same manner as the Example 9.

In this regard, a thickness of the obtained resin film was 25 μm.

### Example 13

A resin film of the Example 13 was formed on the glass substrate in the same manner as the Example 12, except that a thickness of the resin film to be formed on the glass substrate was changed to 16 μm in the forming the resin film (polyamide film).

### Example 14

A resin film of the Example 14 was formed on the glass substrate in the same manner as the Example 12, except that a thickness of the resin film to be formed on the glass substrate was changed to 8 μm in the forming the resin film (polyamide film).

### Example 15

A resin composition of the Example 15 was prepared in the same manner as the Example 9, except that TPC was changed to a combination of TPC (1.803 g, 0.00850 mol) and IPC (0.318 g, 0.00150 mol) as the dichloride component used in the step <3>. Thereafter, a resin film of the Example 15 was formed on the glass substrate by using the resin composition in the same manner as the Example 9.

In this regard, a thickness of the obtained resin film was 25 μm.

### Example 16

A resin film of the Example 16 was formed on the glass substrate in the same manner as the Example 15, except that a thickness of the resin film to be formed on the glass substrate was changed to 17 μm in the forming the resin film (polyamide film).

### Example 17

A resin composition of the Example 17 was prepared in the same manner as the Example 14, except that the following step <5> is further carried out after the step <4>.

<5> TG (triglycidyl isocyanurate) of 5% by weight with respect to the resin composition (polyamide) was added and stirred for more two hours.

Thereafter, a resin film of the Example 17 was formed on the glass substrate by using the resin composition in the same manner as the Example 14.

### Comparative Example 1

A resin composition of the Comparative Example 1 was prepared in the same manner as the Example 1, except that the combination of TPC and IPC was changed to a combination of TPC (1.379 g, 0.00650 mol) and IPC (0.742 g, 0.00350 mol) as the dichloride component used in the step <3>. Thereafter, a resin film of the Comparative Example 1 was formed on the glass substrate by using the resin composition in the same manner as the Example 1.

In this regard, a thickness of the obtained resin film was 22 μm.

### Comparative Example 2

A resin film of the Comparative Example 2 was formed on the glass substrate in the same manner as the Comparative Example 1, except that a thickness of the resin film to be formed on the glass substrate was changed to 15 μm in the forming the resin film (polyamide film).

### Comparative Example 3

A resin film of the Comparative Example 3 was formed on the glass substrate in the same manner as the Comparative Example 1, except that a thickness of the resin film to be formed on the glass substrate was changed to 8 μm in the forming the resin film (polyamide film).

### Comparative Example 4

A resin composition of the Comparative Example 4 was prepared in the same manner as the Example 9, except that TPC was changed to a combination of TPC (1.485 g, 0.00700 mol) and IPC (0.636 g, 0.00300 mol) as the dichloride component used in the step <3>. Thereafter, a resin film of the Comparative Example 4 was formed on the glass substrate by using the resin composition in the same manner as the Example 9.

In this regard, a thickness of the obtained resin film was 25 μm.

### Comparative Example 5

A resin film of the Comparative Example 5 was formed on the glass substrate in the same manner as the Comparative Example 4, except that a thickness of the resin film to be formed on the glass substrate was changed to 16 μm in the forming the resin film (polyamide film).

### Comparative Example 6

A resin film of the Comparative Example 6 was formed on the glass substrate in the same manner as the Comparative Example 4, except that a thickness of the resin film to be formed on the glass substrate was changed to 8 μm in the forming the resin film (polyamide film).

2. Evaluation

The resin film obtained from the resin composition of each of the Examples and the Comparatives Examples was evaluated in accordance with the following methods.

[Total Light Transmittance]

A total light transmittance of the resin film in a D line (sodium line) was measured by using a haze meter (“NDH-2000” produced by NIPPON DENSHOKU INDUSTRIES CO., LTD.).

[Haze Value]

A haze value of the resin film in a D line (sodium line) was measured by using a haze meter (“NDH-2000” produced by NIPPON DENSHOKU INDUSTRIES CO., LTD.).

The total light transmittance and the haze value of the resin film formed from the resin composition obtained in each of the Examples and the Comparative Examples as described above were shown in Table 1 below as results. Then, the results were evaluated.

TABLE 1

| | Composition | | | | | | Resin film | | | | |
|---|---|---|---|---|---|---|---|---|---|---|---|
| | Diamine | | Dichloride | | Amount of rigid | Epoxide | Cure | | | Total light | |
| | PFMB | DAB | TPC | IPC | structure | TG | Temp. | Time | Thickness | transmittance | Haze value |
| | mol % | mol % | mol % | mol % | mol % | wt % | ° C. | min. | μm | % | % |
| Ex. 1 | 100 | 0 | 95 | 5 | 97.5 | 0 | 350 | 30 | 23 | 50.5 | 99.2 |
| Ex. 2 | 100 | 0 | 95 | 5 | 97.5 | 0 | 350 | 30 | 14 | 55.1 | 96.5 |
| Ex. 3 | 100 | 0 | 95 | 5 | 97.5 | 0 | 350 | 30 | 8 | 62 | 68 |
| Ex. 4 | 100 | 0 | 90 | 10 | 95 | 0 | 350 | 30 | 25 | 65.1 | 44.9 |
| Ex. 5 | 100 | 0 | 90 | 10 | 95 | 0 | 350 | 30 | 15 | 72.4 | 33.3 |
| Ex. 6 | 100 | 0 | 90 | 10 | 95 | 0 | 350 | 30 | 8 | 80.1 | 15.2 |
| Ex. 7 | 100 | 0 | 80 | 20 | 90 | 0 | 350 | 30 | 23 | 82.2 | 12.3 |
| Ex. 8 | 100 | 0 | 80 | 20 | 90 | 0 | 350 | 30 | 18 | 83.3 | 8.1 |
| Ex. 9 | 95 | 5 | 100 | 0 | 97.5 | 0 | 350 | 30 | 25 | 48.4 | 98.8 |
| Ex. 10 | 95 | 5 | 100 | 0 | 97.5 | 0 | 350 | 30 | 15 | 53.4 | 95.7 |
| Ex. 11 | 95 | 5 | 100 | 0 | 97.5 | 0 | 350 | 30 | 7 | 63.4 | 69 |
| Ex. 12 | 95 | 5 | 95 | 5 | 95 | 0 | 350 | 30 | 25 | 65.5 | 45.4 |
| Ex. 13 | 95 | 5 | 95 | 5 | 95 | 0 | 350 | 30 | 16 | 71.8 | 31 |
| Ex. 14 | 95 | 5 | 95 | 5 | 95 | 0 | 350 | 30 | 8 | 79.9 | 14.9 |
| Ex. 15 | 95 | 5 | 85 | 15 | 90 | 0 | 350 | 30 | 25 | 81.5 | 11.9 |
| Ex. 16 | 95 | 5 | 85 | 15 | 90 | 0 | 350 | 30 | 17 | 83.8 | 7.6 |
| Ex. 17 | 95 | 5 | 95 | 5 | 95 | 5 | 280 | 30 | 8 | 82.1 | 13.9 |
| Comp. Ex. 1 | 100 | 0 | 65 | 35 | 82.5 | 0 | 350 | 30 | 22 | 89.2 | 0.2 |
| Comp. Ex. 2 | 100 | 0 | 65 | 35 | 82.5 | 0 | 350 | 30 | 15 | 89 | 0.2 |
| Comp. Ex. 3 | 100 | 0 | 65 | 35 | 82.5 | 0 | 350 | 30 | 8 | 88.8 | 0.2 |
| Comp. Ex. 4 | 95 | 5 | 70 | 30 | 82.5 | 0 | 350 | 30 | 25 | 88.6 | 0.3 |
| Comp. Ex. 5 | 95 | 5 | 70 | 30 | 82.5 | 0 | 350 | 30 | 16 | 88.6 | 0.2 |
| Comp. Ex. 6 | 95 | 5 | 70 | 30 | 82.5 | 0 | 350 | 30 | 8 | 88.6 | 0.2 |

As shown in Table 1, in each of the resin films obtained in the Examples, the haze value of the resin film was 5% or more. In contrast, sufficient results were not obtained in each of the resin films obtained in the Comparative Examples.

Further, each of the resin films obtained in the Examples has high total light transmittance.

What is claimed is:

1. A resin composition comprising:
a crystalline polymer; and
a solvent dissolving the crystalline polymer,
wherein the resin composition is used to form a layer, and a haze value of the layer is 5% or more.

2. The resin composition according to claim 1, wherein the crystalline polymer is an aromatic polyamide.

3. The resin composition according to claim 2, wherein the aromatic polyamide contains a carboxyl group.

4. The resin composition according to claim 2, wherein the aromatic polyamide contains a rigid structure in an amount of 85 mol % or more.

5. The resin composition according to claim 4, wherein the rigid structure is a repeating unit represented by the following general formula: 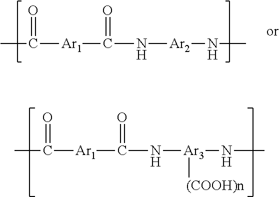
where n represents an integer number of 1 to 4, Ar₁ is represented by the following general formula (A) or (B): 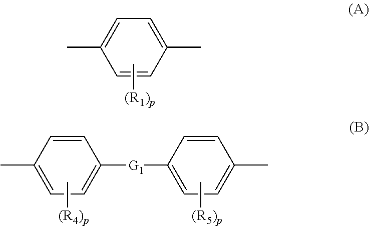
(where p=4; each of R₁, R₄ and R₅ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₁ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).); and Ar₂ is represented by the following general formula (C) or (D): 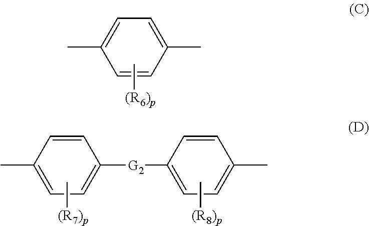
(where p=4; each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₂ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).), and Ar₃ is represented by the following general formula (E) or (F): 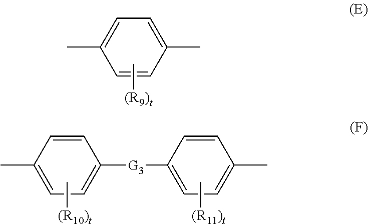
(where t=1 to 3; each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₃ is selected from the group consisting of a covalent bond, a CH₂ group, a C(CH₃)₂ group, a C(CF₃)₂ group, a C(CX₃)₂ group (X represents a halogen atom.), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).).

6. The resin composition according to claim 5, wherein the rigid structure contains at least one of a structure derived from 4,4′-diamino-2,2′-bistrifluoromethyl benzidine (PFMB), a structure derived from terephthaloyl dichloride (TPC), a structure derived from 4,4′-diaminodiphenic acid (DADP), and a structure derived from 3,5-diaminobenzoic acid (DAB).

7. The resin composition according to claim 2, wherein the aromatic polyamide is a wholly aromatic polyamide.

8. The resin composition according to claim 2, wherein the aromatic polyamide contains one or more functional groups that can react with an epoxy group, and
wherein the resin composition further comprises a multifunctional epoxide.

9. The resin composition according to claim 8, wherein at least one terminal of the aromatic polyamide is the functional group that can react with the epoxy group.

10. The resin composition according to claim 8, wherein the multifunctional epoxide is an epoxide containing two or more glycidyl epoxy groups, or an epoxide containing two or more alicyclic groups.

11. The resin composition according to claim 8, wherein the multifunctional epoxide is selected from the group consisting of general structures (α) and (β): 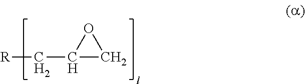
(where l represents the number of glycidyl group, and R is selected from the group comprising: 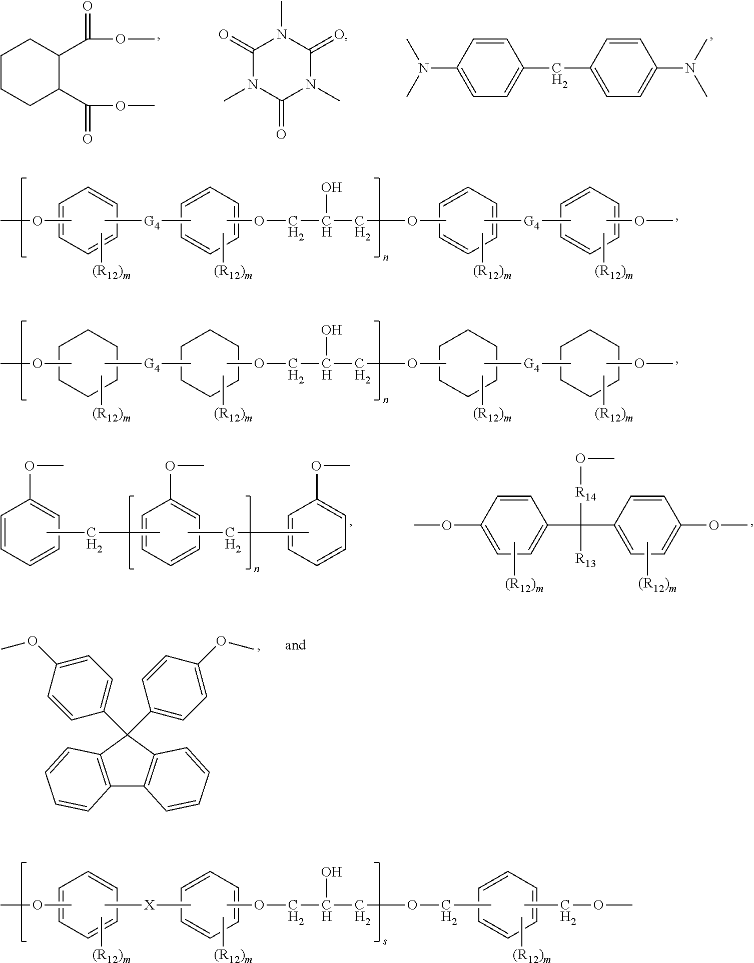
where m=1 to 4, and n and s are the average number of units and independently range from of 0 to 30;
where each of R₁₂ is same or different, and selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them; and G₄ is selected from the group consisting of a covalent bond, a CH₂ group, a C(CH₃)₂ group, a C(CF₃)₂ group, a C(CX₃)₂ group (X represents a halogen atom); a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group, R₁₃ is a hydrogen or methyl group, and R₁₄ is a divalent organic group.).) 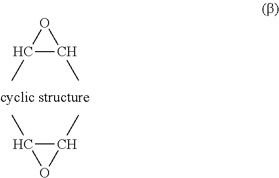
(where the cyclic structure is selected from the group comprising: 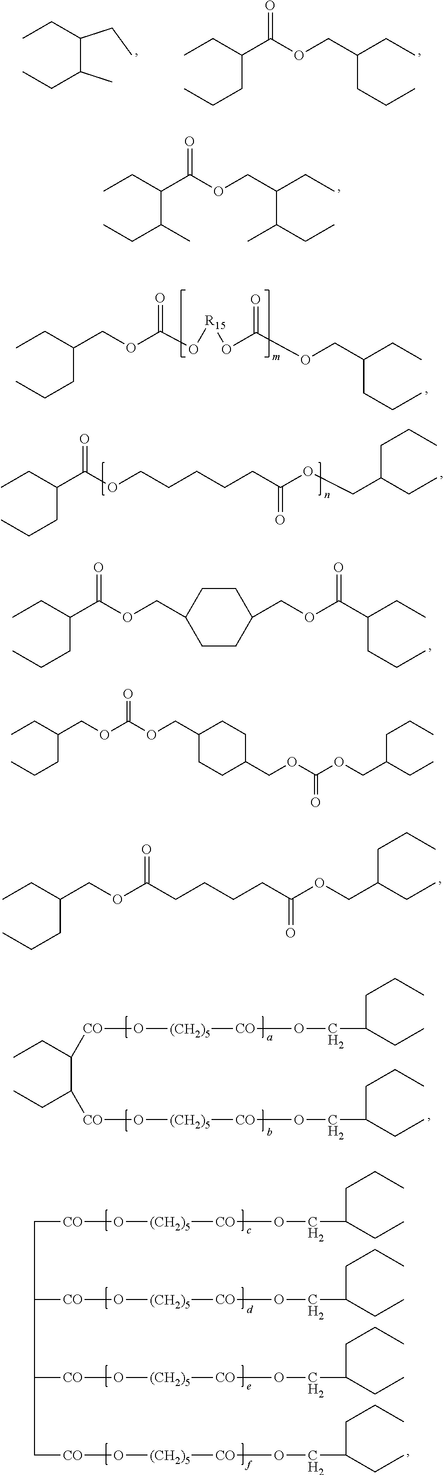 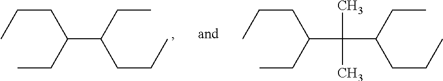
where R₁₅ is an alkyl chain having a carbon number of 2 to 18, the alkyl chain may be a straight chain, a branched chain, or a chain having cyclic skeleton, and
where each of m and n is independently integer number of 1 to 30, and each of a, b, c, d, e and f is independently integer number of 0 to 30.).

12. The resin composition according to claim 8, wherein the multifunctional epoxide is selected from the group comprising: 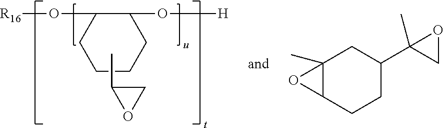
(where R₁₆ is an alkyl chain having a carbon number of 2 to 18, the alkyl chain may be a straight chain, a branched chain, or a chain having cyclic skeleton, and
where each of t and u is independently integer number of 1 to 30.)

13. The resin composition according to claim 2, wherein at least one terminal of the aromatic polyamide is end-capped.

14. The resin composition according to claim 1, wherein a total light transmittance of the layer in a sodium line (D line) is 40% or more.

15. The resin composition according to claim 1, wherein the resin composition further contains an inorganic filler.

16. A substrate used for forming an electronic element thereon, comprising:
a plate-like base member having a first surface and a second surface opposite to the first surface; and
an electronic element formation layer provided at a side of the first surface of the base member and configured to be capable of forming the electronic element on the electronic element formation layer,
wherein the electronic element formation layer contains a crystalline polymer and a haze value of the electronic element formation layer is 5% or more.

17. The substrate according to claim 16, wherein a coefficient of thermal expansion (CTE) of the electronic element formation layer is 100 ppm/K or less.

18. The substrate according to claim 16, wherein an average thickness of the electronic element formation layer is in the range of 1 to 50 μm.

19. The substrate according to claim 16, wherein the electronic element is an organic EL element.

20. A method of manufacturing an electronic device, comprising:
preparing a substrate, the substrate including,
a plate-like base member having a first surface and a second surface opposite to the first surface, and
an electronic element formation layer provided at a side of the first surface of the base member,
wherein the electronic element formation layer is used to form an electronic element on the electronic element formation layer and contains a crystalline polymer, and
wherein a haze value of the electronic element formation layer is 5% or more;
forming the electronic element on a surface of the electronic element formation layer opposite to the base member;
forming a cover layer so as to cover the electronic element;
irradiating the electronic element formation layer with light to thereby peel off the electronic element formation layer from the base member in an interface between the base member and the electronic element formation layer; and
separating the electronic device including the electronic element, the cover layer and the electronic element formation layer from the base member.

21. The method according to claim 20, wherein a coefficient of thermal expansion (CTE) of the electronic element formation layer is 100 ppm/K or less.

22. The method according to claim 20, wherein an average thickness of the electronic element formation layer is in the range of 1 to 50 μm.

23. The method according to claim 20, wherein the crystalline polymer is an aromatic polyamide.

24. The method according to claim 23, wherein the aromatic polyamide contains a carboxyl group.

25. The method according to claim 23, wherein the aromatic polyamide contains a rigid structure in an amount of 85 mol % or more.

26. An electronic device manufactured by using the method defined by claim 20.
